(19) United States
(12) Patent Application Publication
(10) Pub. No.: US 2026/0274674 A1
(43) Pub. Date: Sep. 17, 2026

(54) FORMATION OF GRAPHENE FILMS FROM SOLID BIOMASS-DERIVED CARBON SOURCES BY CHEMICAL VAPOR DEPOSITION

(71) Applicant: City University of Hong Kong, Hong Kong (CN)

(72) Inventors: Thuc Hue LY, Hong Kong (CN); Quoc Huy THI, Hong Kong (CN)

(73) Assignee: City University of Hong Kong, Hong Kong (CN)

(21) Appl. No.: 19/550,400

(22) Filed: Feb. 26, 2026

Related U.S. Application Data
(60) Provisional application No. 63/772,434, filed on Mar. 14, 2025.

(51) Int. Cl. C01B 32/186; C23C 16/26; C23C 16/44; C23C 16/458; C23C 16/46; C23C 16/56

(52) U.S. Cl. CPC C01B 32/186; C23C 16/4408; C23C 16/458; C23C 16/46; C23C 16/56; C01B 2204/02; C01P 2002/82; C01P 2002/88; C01P 2004/04; C23C 16/26

(57) ABSTRACT

A method of forming a graphene film based on chemical vapor deposition includes heating a metal substrate located in a first heating zone of a CVD reactor so as to enable graphene growth on the metal substrate and heating a solid biomass-derived carbon source comprising volatilizable carbon-containing species located in a second heating zone of the CVD reactor so as to volatilize the carbon-containing species from the solid biomass-derived carbon source. The second heating zone is upstream of and spatially separated from the first heating zone. The method further includes providing a flow of carrier gas from the second heating zone to the first heating zone to facilitate transport of the volatilized carbon-containing species to the metal substrate, thereby enabling formation of a graphene film on the metal substrate. At least part of the heating of the metal substrate, at least part of the heating of the solid biomass-derived carbon source, and at least part of the providing of the flow of carrier gas are performed simultaneously.

The present application claims priority from U.S. Provisional Application No. 63/772,434 filed on Mar. 14, 2025, “FORMATION OF GRAPHENE FILMS FROM SOLID BIOMASS-DERIVED CARBON SOURCES BY CHEMICAL VAPOR DEPOSITION”, the content of which being hereby incorporated by reference in its entirety.

### TECHNICAL FIELD

The present invention relates to formation of graphene films from solid biomass-derived carbon sources by chemical vapor deposition (CVD).

### BACKGROUND

Graphene is a two-dimensional (2D) carbon material including a single atomic layer of carbon atoms arranged in a hexagonal lattice. Owing to its electrical, mechanical, and thermal properties, graphene is considered to be suitable for a wide range of applications.

To date, various methods for synthesizing graphene have been developed. Among these methods, CVD has emerged as a promising technique due to its suitability for large-area growth, controllable film quality, and scalability for industrial production.

For example, in an existing CVD process, graphene is formed through the thermal decomposition of carbon-containing precursor gases on a metal substrate under controlled temperature and pressure conditions. A gaseous hydrocarbon precursor, such as methane or ethylene, is introduced into a reaction chamber and adsorbs onto a surface of the metal substrate. Upon exposure to elevated temperatures, the precursor molecules dissociate into carbon species such as carbon atoms. These carbon species diffuse across or on the metal surface and aggregate at energetically favorable sites, thereby forming initial graphene nuclei on the metal surface. Continued surface diffusion and incorporation of carbon species result in lateral growth of the nuclei, ultimately producing a graphene layer on the substrate.

More recently, environmentally sustainable or “green” approaches for synthesizing graphene have been investigated with the aim to improve synthesis efficiency, reduce production costs, and minimize environmental impact of the synthesis process. For example, some existing green synthesis techniques produce graphene in powder form by reducing graphene oxide using reducing agents derived from food waste. In such methods, graphene oxide is obtained through chemical exfoliation of graphite and subsequently reduced to form graphene powder. However, such green synthesis approaches have generally been limited to producing powder-based graphene materials.

Accordingly, there remains a need for improved graphene synthesis techniques that can combine the scalability and quality of the CVD process with environmentally friendly and cost-effective precursor source.

### SUMMARY OF THE INVENTION

In a first aspect, there is provided a method of forming a graphene film based on chemical vapor deposition (CVD). The method comprises heating a metal substrate located in a first heating zone of a CVD reactor so as to enable graphene growth on the metal substrate, and heating a solid biomass-derived carbon source comprising volatilizable carbon-containing species located in a second heating zone of the CVD reactor so as to volatilize the carbon-containing species from the solid biomass-derived carbon source. The second heating zone is arranged upstream of and spatially separated from the first heating zone. The method further comprises providing a flow of carrier gas from the second heating zone to the first heating zone to facilitate transport of the volatilized carbon-containing species to the metal substrate, thereby enabling formation of a graphene film on the metal substrate. At least part of the heating of the metal substrate, at least part of the heating of the solid biomass-derived carbon source, and at least part of the providing of the flow of carrier gas are performed simultaneously.

In one embodiment of the first aspect, the metal substrate and the solid biomass-derived carbon source are arranged in a semi-closed reaction chamber. The semi-closed reaction chamber may comprise a first portion located in the first heating zone and a second portion located in the second heating zone. The semi-closed reaction chamber may be configured to enable flow of the flow of carrier gas from the second portion to the first portion and to partially confine the volatilized carbon-containing species without pressure buildup. The semi-closed reaction chamber may not be sealed or pressurized. In one example, the semi-closed reaction chamber may comprise a tubular reaction chamber with open ends. In one example, the semi-closed reaction chamber may be provided by one or more quartz tubes.

In one embodiment of the first aspect, the method further comprises, prior to heating the metal substrate, heating the solid biomass-derived carbon source, and providing the flow of carrier gas: arranging the metal substrate in the first heating zone and the solid biomass-derived carbon source in the second heating zone. For example, the arranging may include placing the metal substrate in a first container having open ends, placing the solid biomass-derived carbon source in a second container having open ends, and placing the first container in the first heating zone and the second container in the second heating zone such that the first container and the second container are connected at their open ends to define the semi-closed reaction chamber. The first container and the second container may each enable fluid flow therethrough via their respective open ends. In one example, the first container and the second container may have the same shape and the same size. In one example, the first container and the second container may be tubular. In one example, the first container and the second container may each include a quartz tube.

In one embodiment of the first aspect, the method further comprises, prior to heating the metal substrate, heating the solid biomass-derived carbon source, and providing the flow of carrier gas: purging the semi-closed reaction chamber. In one example, the purging may be performed using a flow of gas such as a flow of carrier gas.

In one embodiment of the first aspect, heating the metal substrate comprises heating the first heating zone in which the metal substrate is arranged. For example, heating the first heating zone may include operating one or more heating devices of the CVD reactor, e.g., based on a heating program.

In one embodiment of the first aspect, heating the solid biomass-derived carbon source comprises heating the second heating zone in which the solid biomass-derived carbon source is arranged. For example, heating the second heating zone may include operating one or more heating devices of the CVD reactor, e.g., based on a heating program.

In one embodiment of the first aspect, heating the first heating zone comprises heating the first heating zone at a first heating rate to reach a first temperature and then maintaining the first heating zone at approximately the first temperature (e.g., holding the temperature approximately at the first temperature within normal process tolerances).

In one embodiment of the first aspect, heating the second heating zone comprises heating the second heating zone at a second heating rate to reach a second temperature and then maintaining the second heating zone at approximately the second temperature (e.g., holding the temperature approximately at the second temperature within normal process tolerances). Optionally, the second heating rate is the same as the first heating rate. Optionally, the second temperature is lower than the first temperature.

Optionally, the first heating rate is in a range of about 20° C./min to about 60° C./min, e.g., about 50° C./min. Optionally, a duration for the first heating zone to reach the first temperature is in a range of about 10 minutes to about 60 minutes. Optionally, the first temperature is in a range of about 1000° C. to about 1100° C. Optionally, the second heating rate is in a range of about 20° C./min to about 60° C./min, e.g., about 50° C./min. Optionally, a duration for the second heating zone to reach the second temperature is in a range of about 10 minutes to about 60 minutes. Optionally, the second temperature is in a range of about 300° C. to about 600° C., or in a range of about 400° C. to about 600° C. Optionally, a decomposition rate of the solid biomass-derived carbon source due to the volatilization of the carbon-containing species is in a range of about 0.01%/° C. to about 0.15%/° C.

In one embodiment of the first aspect, the heating of the second heating zone at the second heating rate is initiated while the first heating zone is maintained at approximately the first temperature and after the first heating zone has been maintained at approximately the first temperature for a first period of time for annealing the metal substrate. Optionally, the first period of time is in a range of about 30 minutes to about 60 minutes.

In one embodiment of the first aspect, the first heating zone is maintained at approximately the first temperature and the second heating zone is maintained at approximately the second temperature simultaneously for a second period of time. Optionally, the second period of time is in a range of about 10 minutes to about 60 minutes.

In one embodiment of the first aspect, the method further comprises, after the second period of time: terminating heating of both the first heating zone and the second heating zone to enable cooling of the first heating zone and the second heating zone. For example, terminating heating may include stopping operation of the one or more heating devices configured to heat the first heating zone and the second heating zone. Active cooling may or may not be employed to cool the first heating zone and the second heating zone. Optionally, the cooling may occur at an average cooling rate in a range of about 10° C./min to 60° C./min.

The metal substrate may refer to a substrate comprising a metal material. The metal substrate may include metal foil, metal sheet, or other metal body capable of supporting graphene growth. In one embodiment of the first aspect, the metal substrate comprises at least one metal foil such as a platinum foil or a copper foil. In one embodiment of the first aspect, the at least one metal foil comprises a first metal foil and a second metal foil separated by a distance. Optionally, the distance is in a range of about 0.5 cm to about 2 cm.

The solid biomass-derived carbon source may refer to a solid material derived from biological matter that contains carbon and is capable of releasing carbon-containing species when subjected to heating. For example, the solid biomass-derived carbon source may comprise food waste, timber or forestry waste or agricultural biomass materials containing carbon-rich organic compounds capable of volatilization upon heating, including but not limited to coffee residue, rice husk, coconut shell, sugarcane bagasse, or combinations thereof, or any type of lignocellulosic waste.

In one embodiment of the first aspect, the solid, biomass-derived carbon source comprises coffee residue. In one example, the volatilizable carbon-containing species may comprise volatilizable aroma molecules. For example, the aroma molecules may comprise 3,5-dimethyl-2-ethylpyrazine, 2,3-diethyl-5-methylpyrazine, 4-ethylguaiacol, or any combinations thereof. In one example, the coffee residue may comprise spent coffee grounds that have been dried prior to the heating. In one example, the coffee residue may comprise spent coffee grounds that have been washed and then dried prior to the heating. Optionally the washing may be performed using water (e.g., about 60° C. to about 100° C.) or ethanol (e.g., about 20° C. to about 60° C.). Optionally the drying may be performed in an oven (e.g., about 60° C. to about 80° C.). In one embodiment of the first aspect, an amount of the coffee residue prior to heating is in a range of about 0.1 mg to about 10 mg, such as about 1 mg or about 2 mg. Optionally, the coffee residue may originate from coffea canephora beans (robusta beans) and/or coffea arabica beans (arabica beans).

In one embodiment of the first aspect, the flow of carrier gas comprises an inert gas. Optionally, the inert gas may comprise argon.

In one embodiment of the first aspect, the method further comprises providing a flow of reducing gas for preventing oxidation on or of the metal substrate. The reducing gas may provide a reducing environment within the CVD reactor and may reduce or suppress oxidation of the metal substrate. Optionally, the reducing gas may comprise hydrogen.

In one embodiment of the first aspect, the flow of reducing gas is combined with the flow of carrier gas as a combined flow. For example, the reducing gas may also function as the carrier gas for facilitating transport of the volatilized carbon-containing species to the metal substrate.

Optionally, a ratio of a flow rate of the inert gas to a flow rate of the reducing gas is in a range of about 10:1 to about 100:1. Optionally, a flow rate of the inert gas is in a range of about 100 sccm to about 200 sccm. Optionally, a flow rate of the reducing gas is in a range of about 2 sccm to about 10 sccm.

In one embodiment of the first aspect, the method further comprises transferring the graphene film formed on the metal substrate to a target substrate using an electrochemical delamination process. The electrochemical delamination process may correspond to bubbling transfer (i.e., a process in which gas bubbles generated electrochemically at an interface between a graphene film and a metal substrate separate the graphene film from the metal substrate).

In one embodiment of the first aspect, the graphene film comprises a single-layer (1L) graphene film.

In a second aspect, there is provided a graphene film obtained using the method of the first aspect.

In a third aspect, there is provided a device comprising a graphene film obtained using the method of the first aspect.

Other features and aspects will become apparent by consideration of the following detailed description and the accompanying drawings. Any feature described herein in relation to one aspect or embodiment may be combined with any other feature described herein in relation to any other aspect or embodiment, as appropriate and applicable.

### BRIEF DESCRIPTION OF THE DRAWINGS

Some embodiments will now be described, with reference to the accompanying drawings, in which:

FIG. 1 is a flowchart illustrating a method of forming a graphene film based on CVD in one embodiment.

FIG. 2 is a schematic diagram illustrating a set-up and a heating program for synthesizing graphene from coffee residue using CVD in one embodiment.

FIG. 3A is an energy dispersive spectrum (EDS) of coffee grounds originating from robusta coffee beans along with a table displaying the elemental composition present in the sample in one embodiment.

FIG. 3B is an EDS of coffee residue originating from the sample in FIG. 3A along with a table displaying the elemental composition present in the sample in one embodiment.

FIG. 4A is an optical image of a single layer graphene grown on a platinum (Pt) foil using coffee residue as precursor in one embodiment.

FIG. 4B is an optical image of a single layer graphene grown on a copper (Cu) foil using coffee residue as precursor in one embodiment.

FIG. 5 is a graph showing Raman spectrums of a single layer graphene grown on the Pt foil and a single layer graphene grown on Cu foil using coffee residue as precursor in one embodiment.

FIG. 6A is an optical image of a single layer graphene (on a SiO₂/Si substrate) transferred from a sample grown on a Pt foil using coffee residue as precursor in one embodiment.

FIG. 6B is an optical image of a single layer graphene (on a SiO₂/Si substrate) transferred from a sample grown on a Cu foil using coffee residue as precursor in one embodiment.

FIG. 7 is a graph showing Raman spectrums of a single layer graphene (on the SiO₂/Si substrate) transferred from a sample grown on a Pt foil and a single layer graphene (on the SiO₂/Si substrate) transferred from a sample grown on a Cu foil, both using coffee residue as precursor, in one embodiment.

FIG. 8 is an atomic force microscope (AFM) topographic image and the corresponding line profile showing thickness of a single layer graphene on a SiO₂/Si substrate transferred from a sample grown on a Pt foil using coffee residue as the precursor in one embodiment.

FIG. 9 is an atomic scale transmission electron microscope (TEM) image and the selected area electron diffraction patterns showing the high crystallinity of a single layer graphene transferred from a sample grown on a Pt foil using coffee residue as precursor in one embodiment.

FIG. 10 is a graph showing Raman spectrums of a single layer graphene grown on a Pt foil using Arabica coffee residue as precursor and a single layer graphene grown on a Pt foil using Robusta coffee residue as precursor in one embodiment.

FIG. 11A is a graph showing thermogravimetric and derivative thermogravimetric (TGA/DTG) analysis of Arabica coffee residue in one embodiment.

FIG. 11B is a graph showing TGA/DTG analysis of Robusta coffee residue in one embodiment.

FIG. 12 is a graph showing the oxygen content on a bare Cu foil, graphene from Robusta coffee residue grown on a Cu foil, and graphene from Arabica coffee residue grown on a Cu foil, before and after immersion in 50% H₂O₂ solution for 3 hours, in one embodiment.

### DETAILED DESCRIPTION OF THE PREFERRED EMBODIMENTS

Embodiments disclosed herein relate to formation of a graphene film from a solid biomass-derived carbon sources by CVD. Embodiments disclosed herein may combine the scalability and quality of the CVD process with environmentally friendly and cost-effective precursor source (carbon source).

As used herein, unless otherwise specified, terms of degree such that “generally”, “about”, “substantially”, or the like, are intended to account for one or more of: manufacture tolerance, degradation, trend, tendency, imperfect practical condition, etc. Further, as used herein, unless otherwise specified, terms such as “connected”, “coupled”, or “mounted” used herein are intended to encompass both direct and indirect connection, coupling, or mounting.

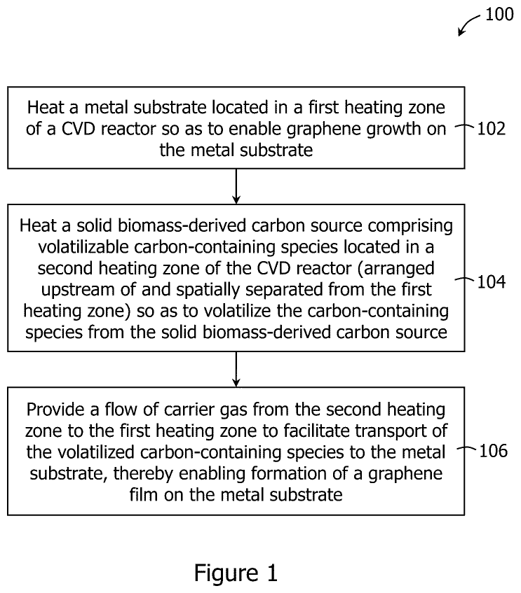

FIG. 1 shows a method 100 of forming a graphene film based on CVD in one embodiment.

The method 100 includes, in 102, heating a metal substrate located in a first heating zone of a CVD reactor so as to enable graphene growth on the metal substrate. For example, 102 may be performed for suitable duration(s) and at suitable temperature(s) sufficient to enable (e.g., promote) graphene growth on the metal substrate.

The metal substrate may refer to a substrate including a metal material. The metal substrate may include metal foil, metal sheet, or other metal body capable of supporting graphene growth. In one embodiment, the metal substrate includes at least one metal foil such as a Pt foil or a Cu foil. In one embodiment, the at least one metal foil includes two or more metal foils, e.g., at least a first metal foil (e.g., Pt foil) and a second metal foil (e.g., Cu foil) separated by a distance. In one example implementation, the distance is in a range of about 0.5 cm to about 2 cm.

The method 100 includes, in 104, heating a solid biomass-derived carbon source including volatilizable carbon-containing species located in a second heating zone of the CVD reactor so as to volatilize the carbon-containing species from the solid biomass-derived carbon source. The second heating zone is arranged upstream of and spatially separated from the first heating zone. For example, 104 may be performed for suitable duration(s) and at suitable temperature(s) sufficient to volatilize (i.e., release due to heating) the carbon-containing species (e.g., carbon-containing molecular fragments, radicals, or compounds) from the solid biomass-derived carbon source. The volatilized carbon-containing species may be in gas phase.

The solid biomass-derived carbon source may refer to a solid material derived from biological matter that contains carbon and may be capable of releasing carbon-containing species when subjected to heating. For example, the solid biomass-derived carbon source may include food waste or agricultural biomass materials containing carbon-rich organic compounds capable of volatilization upon heating, including but not limited to coffee residue, rice husk, coconut shell, sugarcane bagasse, or combinations thereof, or any type of lignocellulosic waste. In one embodiment, the solid, biomass-derived carbon source includes coffee residue. In one example, the volatilizable carbon-containing species may include volatilizable aroma molecules. For example, the aroma molecules may include 3,5-dimethyl-2-ethylpyrazine, 2,3-diethyl-5-methylpyrazine, 4-ethylguaiacol, or any combinations thereof. In one example, the coffee residue may include spent coffee grounds that have been dried prior to the heating. In one example, the coffee residue may include spent coffee grounds that have been washed and then dried prior to the heating. In one example implementation, the washing may be performed using water (e.g., about 60° C. to about 100° C.) or ethanol (e.g., about 20° C. to about 60° C.). In one example implementation, the drying may be performed in an oven (e.g., about 60° C. to about 80° C.). In one example implementation, an amount of the coffee residue prior to heating is in a range of about 0.1 mg to about 10 mg, such as about 1 mg or about 2 mg. In one example implementation, the coffee residue may originate from coffea canephora beans (robusta beans) and/or coffea arabica beans (arabica beans).

In method 100, the CVD reactor may refer to an apparatus configured to perform CVD. For example, the CVD reactor may include one or more reaction chambers, one or more heating devices, and one or more gas delivery systems. The CVD reactor may have any suitable geometry or furnace configuration. The first heating zone may refer to a first spatial region of the CVD reactor that is configured to be heated by one or more heating devices. The first heating zone may correspond to a temperature field within the CVD reactor. The second heating zone may refer to a second spatial region of the CVD reactor that is configured to be heated by one or more heating devices. The second heating zone may correspond to a temperature field within the CVD reactor. The first and second heating zones may refer to spatially distinct regions of the CVD reactor that may be at the same temperature or at different temperatures. The first and second heating zones may or may not include a physical gap or separation therebetween. The second heating zone is arranged upstream of the first heating zone with respect to a gas flow direction in the CVD chamber.

In one embodiment, the metal substrate and the solid biomass-derived carbon source may be arranged in a semi-closed reaction chamber. The semi-closed reaction chamber may include a first portion located in the first heating zone and a second portion located in the second heating zone. The semi-closed reaction chamber may be configured to enable flow of the flow of carrier gas from the second portion to the first portion and to partially confine the volatilized carbon-containing species without pressure buildup. The semi-closed reaction chamber may not be sealed or pressurized. In one example, the semi-closed reaction chamber may include a tubular reaction chamber with open ends. In one example, the semi-closed reaction chamber may be provided by one or more quartz tubes.

In one embodiment, the method 100 may further include, prior to 102, 104, and 106, arranging the metal substrate in the first heating zone and the solid biomass-derived carbon source in the second heating zone. For example, the arranging may include placing the metal substrate in a first container having open ends, placing the solid biomass-derived carbon source in a second container having open ends, and placing the first container in the first heating zone and the second container in the second heating zone such that the first container and the second container are connected at their open ends to define the semi-closed reaction chamber. The first container and the second container may each enable fluid flow therethrough via their respective open ends. In one example, the first container and the second container may have the same shape and the same size. In one example, the first container and the second container may be tubular. In one example, the first container and the second container may each include a quartz tube.

In one embodiment, the method 100 may further include, prior to 102, 104, and 106, purging the semi-closed reaction chamber. In one example, the purging may be performed using with a flow of gas such as a/the flow of carrier gas.

The method 100 includes, in 106, providing a flow of carrier gas from the second heating zone to the first heating zone to facilitate transport of the volatilized carbon-containing species to the metal substrate, thereby enabling formation of a graphene film on the metal substrate.

For example, in 106, the flow of carrier gas may include an inert gas such as argon. In one embodiment, the method 100 may further include providing a flow of reducing gas, such as hydrogen, for preventing oxidation on or of the metal substrate. The reducing gas may provide a reducing environment within the CVD reactor and may reduce or suppress oxidation of the metal substrate. In one embodiment, the flow of reducing gas is combined with the flow of carrier gas as a combined flow. For example, the reducing gas may also function as the carrier gas for facilitating transport of the volatilized carbon-containing species to the metal substrate. In one example implementation, a ratio of a flow rate of the inert gas to a flow rate of the reducing gas is in a range of about 10:1 to about 100:1. In one example implementation, a flow rate of the inert gas is in a range of about 100 standard cubic centimeters per minute (sccm) to about 200 sccm. In one example implementation, a flow rate of the reducing gas is in a range of about 2 sccm to about 10 sccm.

In method 100, at least part of 102, at least part of 104, and at least part of 106 are performed simultaneously. That is, in at least one time instant, 102, 104, and 106 occur at the same time.

In one example implementation, 102 may include heating the first heating zone in which the metal substrate is arranged. For example, heating the first heating zone may include operating one or more heating devices of the CVD reactor, e.g., based on a heating program. For example, heating the first heating zone may include heating the first heating zone at a first heating rate to reach a first temperature and then maintaining the first heating zone at approximately the first temperature (e.g., holding the temperature approximately at the first temperature within normal process tolerances).

In one example implementation, 104 may include heating the second heating zone in which the solid biomass-derived carbon source is arranged. For example, heating the second heating zone may include operating one or more heating devices of the CVD reactor, e.g., based on a heating program. For example, heating the second heating zone may include heating the second heating zone at a second heating rate to reach a second temperature and then maintaining the second heating zone at approximately the second temperature (e.g., holding the temperature approximately at the second temperature within normal process tolerances).

The second heating rate may or may not be the same as the first heating rate. The second temperature may or may not be lower than the first temperature. In one example implementation, the first heating rate is in a range of about 20° C./min to about 60° C./min, e.g., about 50° C./min. In one example implementation, a duration for the first heating zone to reach the first temperature is in a range of about 10 minutes to about 60 minutes. In one example implementation, the first temperature is in a range of about 1000° C. to about 1100° C. In one example implementation, the second heating rate is in a range of about 20° C./min to about 60° C./min, e.g., about 50° C./min. In one example implementation, a duration for the second heating zone to reach the second temperature is in a range of about 10 minutes to about 60 minutes. In one example implementation, the second temperature is in a range of about 300° C. to about 600° C., or in a range of about 400° C. to about 600° C. In one example implementation, a decomposition rate of the solid biomass-derived carbon source due to the volatilization of the carbon-containing species is in a range of about 0.01%/° C. to about 0.15%/° C.

In one embodiment, the heating of the second heating zone at the second heating rate may be initiated while the first heating zone is maintained at approximately the first temperature and after the first heating zone has been maintained at approximately the first temperature for a first period of time for annealing the metal substrate. In one example implementation, the first period of time is in a range of about 30 minutes to about 60 minutes.

In one embodiment, the first heating zone may be maintained at approximately the first temperature and the second heating zone may be maintained at approximately the second temperature simultaneously for a second period of time. In one example implementation, the second period of time is in a range of about 10 minutes to about 60 minutes.

In one embodiment, the method 100 may further include, after the second period of time: terminating heating of both the first heating zone and the second heating zone to enable cooling of the first heating zone and the second heating zone. For example, terminating heating may include stopping operation of the one or more heating devices configured to heat the first heating zone and the second heating zone. Active cooling may or may not be employed to cool the first heating zone and the second heating zone. In one example implementation, the cooling may occur at an average cooling rate in a range of about 10° C./min to 60° C./min.

In one embodiment, the method 100 may further include transferring the graphene film formed on the metal substrate to a target substrate (e.g., a SiO2/Si substrate) using an electrochemical delamination process. The electrochemical delamination process may correspond to bubbling transfer (i.e., a process in which gas bubbles generated electrochemically at an interface between a graphene film and a metal substrate separate the graphene film from the metal substrate).

In one embodiment, the graphene film formed using the method 100 may include or may be a single-layer (1L) graphene film.

The following disclosure provides some example implementations of method 100 in some embodiments. In other words, these embodiments include the operations associated with 102, 104, and 106 disclosed herein.

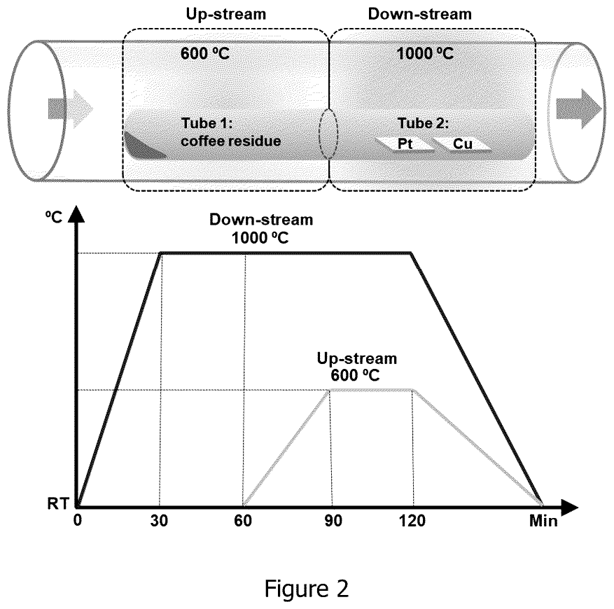

In one example implementation of method 100 in one embodiment, there is provided a method of using coffee residue as precursor for direct growth of single layer (1L) graphene on a metal substrate (e.g., Pt, Cu, etc.) by CVD. During the process in this embodiment, coffee residue is used as carbon source for graphene growth, metal foil (e.g., Pt, Cu, etc.) is used as a growth substrate (i.e., a substrate on which graphene is grown), hydrogen is used as a reducing gas to prevent the oxidation on metal, and argon is used as carrier gas. in this embodiment, high-quality 1L-graphene is prepared using double-zones CVD system shown in FIG. 2.

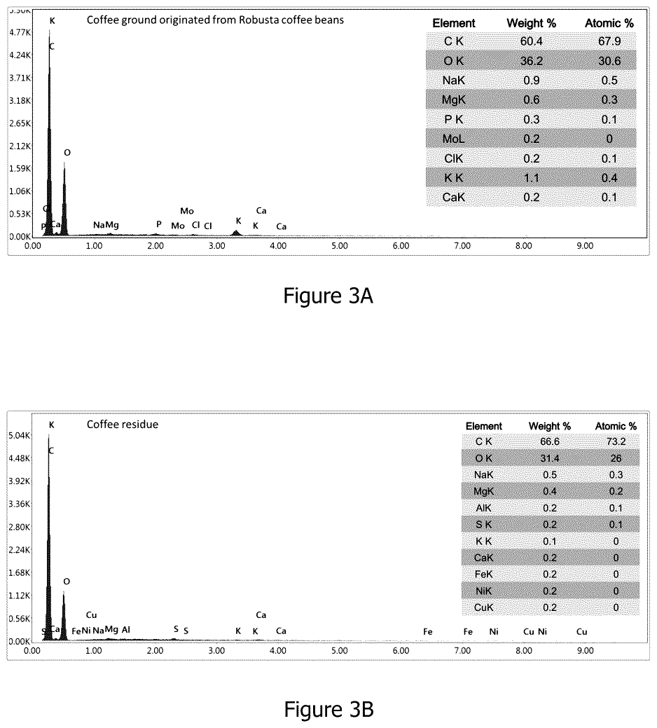

In this embodiment, the aroma molecules and other volatile organic components in the coffee residue act as the precursor for the growth of full-film graphene on the metal substrate. In this embodiment, the coffee residue is originated from robusta coffee beans, which is relatively cheap and popular in Asia. In addition, robusta coffee beans may contain a higher ratio of caffeine and aroma molecules, such as 3,5-dimethyl-2-ethypyrazine, 2,3-diethyl-5-methypyrazine, and 4-ethyguaiacol. These molecules, with their hexagonal ring structures, may assist in promoting the nucleation of graphene. The robusta coffee ground sample may contain large amount of carbon and oxygen and a small amount of metal ions, as shown in FIG. 3A. The amount of metals ions in the coffee residue (obtained by washing and drying the robusta coffee ground sample) is reduced and become neglectable, as shown in FIG. 3B.

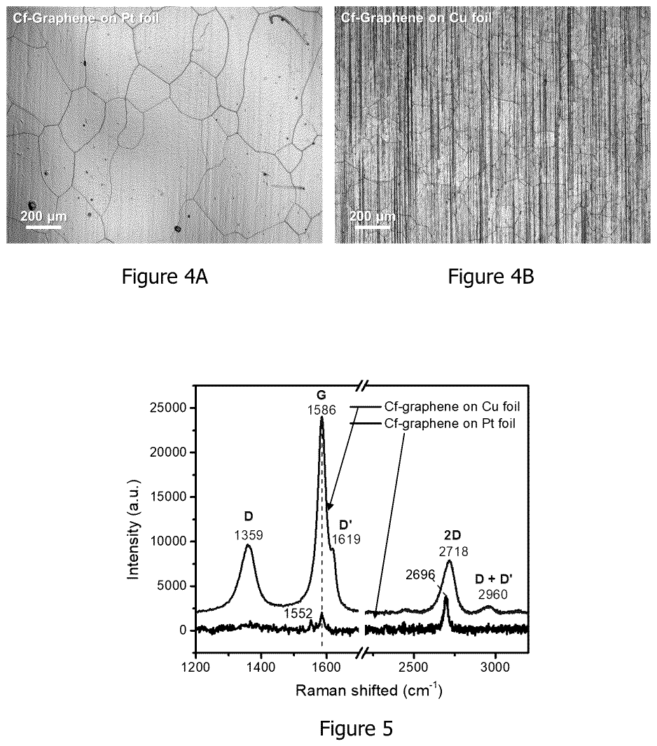

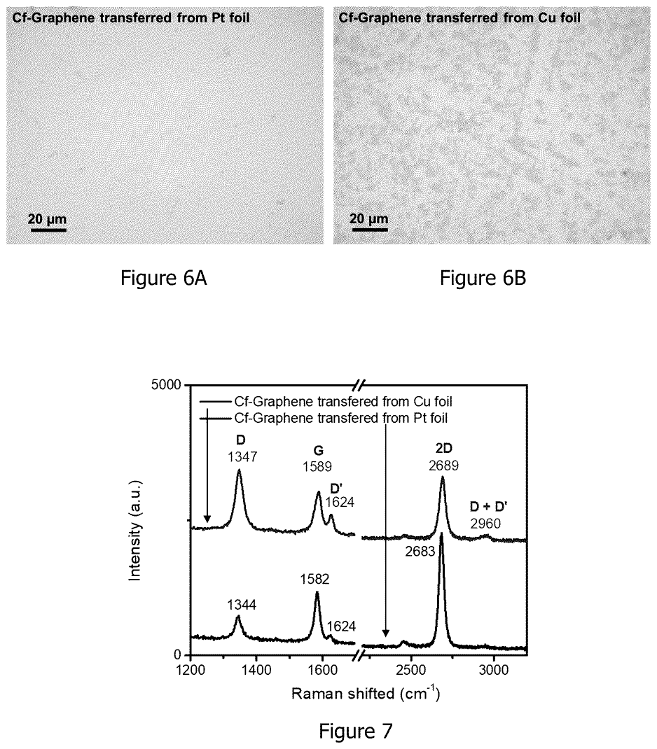

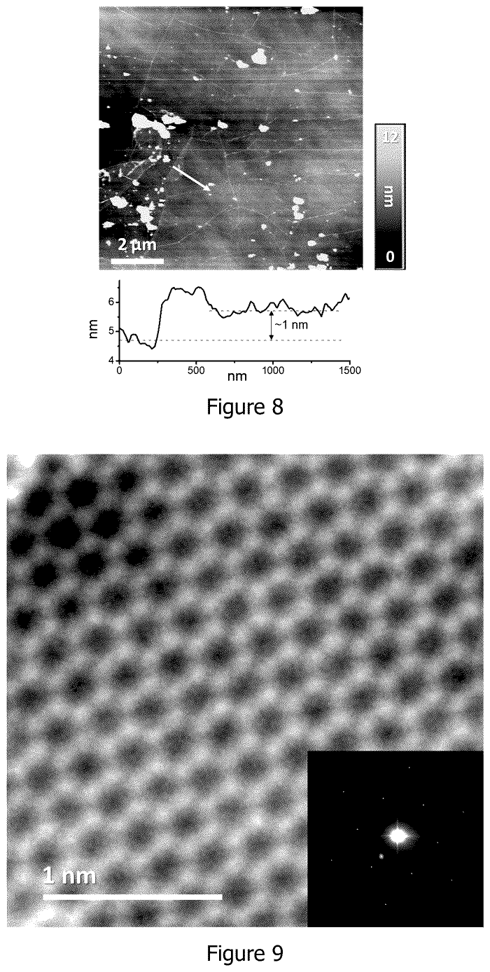

The method for direct growth of 1L-graphene on different metal substrates from coffee residue can obtain high-quality full-film graphene which may be comparable with common CVD growth method, as illustrated in FIGS. 4A, 4B, and 5. The 1L-graphene on the growth substrate can be transferred to a SiO₂/Si substrate, as illustrated in FIGS. 6A, 6B, and 7, using bubbling transfer method to recycle the metal foil for further use. As illustrated in FIGS. 8 and 9, the graphene product obtained using the method in this embodiment has a single layer thickness and has a relatively high crystallinity that is suitable for multiple applications.

In this embodiment, the successful growth of 1L-graphene from coffee residue is enabled by placing the coffee residue and the growth substrate separately in two test tubes and then connecting the open sides or ends of the two test tubes to each other to form a semi-closed reaction chamber. Volatile molecules from the coffee residue may be volatilized (e.g., sublimed) and transferred onto the growth substrate by thermal gradient and/or gas flow. The semi-closed reaction chamber may help to conserve the reactants, without building up pressure in the chamber. This may help to maintain the stability of the growth process.

In some example implementations of method 100 in some embodiments, there is provided a method for direct growth of 1L-graphene from coffee residue using double-zone CVD. The method may include: (1) Place a Pt foil and/or a Cu foil in a first quartz test tube, then load the first quartz test tube horizontally into the center of a downstream heating zone of the tube furnace of the CVD reactor; (2) Place an amount of coffee residue into a second quartz test tube, then load the second quartz test tube into the center of an upstream heating zone of the tube furnace. Connect the open sides of the two quartz test tubes to each other to form a semi-closed reaction chamber; (3) Provide argon and hydrogen (gas) flow, then set the heating program for the tube furnace (for the upstream and downstream zones); (4) Heat up the downstream zone and anneal for a period of time before heating up the upstream zone to start the growth process; and (5) After growing, cool down both heating zones to room temperature before taking the samples (the grown graphene samples) out. In these embodiments, the sizes, shapes, and/or constructions of quartz test tubes and metal foil(s) in (1) and (2) may be varied, e.g., depending on the size, shape and/or construction of the tube furnace of the CVD reactor. For example, the amount of coffee residue load in (2) may be in the range of 0.1 mg to 10 mg. For example, the gas flow ratio of argon/hydrogen in (2) may be in the range of 10:1 to 100:1. For example, the ramping (heating) time of both heating zones in (3) may be in the range of 10 minutes to 60 minutes. For example, the desired temperature of the downstream zone in (4) may be in the range of 1000° C. to 1100° C. For example, the annealing time in downstream zone may be about 30 minutes to 60 minutes before heating up the upstream zone. For example, the desired temperature of upstream zone in (4) may be in the range of 300° C. to 600° C. For example, the growth time, when both heating zones are their respective desired temperature, may be in the range of 10 minutes to 60 minutes. For example, the average cooling rate in (5) may be in the range of 10° C./min to 60° C./min.

In a reference CVD synthesis process which uses gaseous precursors, only a small percentage of carbon-containing gases (precursors) are converted into graphene during the growth process (the remaining, large percentage of carbon-containing gases are exhausted from the reaction chamber). Also, many gaseous carbon-containing precursors may cause increased greenhouse effects, and some of them may be highly hazardous. For example, ethylene (an example gaseous carbon-containing precursor) may cause headache, dizziness, fatigue, confusion, and unconsciousness when human is exposed to it. These chronic health effects may last for a long time (e.g., months or years). Additionally, the synthesis in this reference process may require ultra-high purity precursors for producing high-quality graphene. These factors may raise concerns regarding pollution and efficiency in industrial-scale production.

Food waste recycling is one of the major global concerns. With the rapid growth of the world's population, the amount of food waste has increased dramatically, becoming a significant contributor to environmental pollution and greenhouse gas emissions. It is estimated that approximately 1.3 billion tons of food are discarded annually, accounting for about 10% of global greenhouse gas emissions. In response, the food waste recycling market has developed rapidly. Despite this growth, many food waste recycling programs face critical challenges, particularly the high costs associated with the collection, transportation, and categorization of waste materials. As a result, recycled products are often more expensive than conventional products, which limits their commercial viability. Among various food waste recycling initiatives, campaigns focused on recycling coffee residues have been implemented for more than a decade. However, such programs have declined due to concerns related to disease transmission and public health risks during the collection process.

In some example implementations of method 100 in some embodiments, there is provided a method for directly growing high-quality 1L-graphene on a metal foil from coffee residue. This method does not require high purity precursor gases in the reference CVD graphene synthesis process. The solid precursor, coffee residue, is cheap or at zero-cost (e.g., often as a leftover). The graphene prepared using this method may be comparable with commercialize graphene products and may be used for applications such as electronic, optoelectronic, biomedical, sensing, protection coating, among others. In some example implementations, the method may offer superiority over the reference CVD method in terms of production cost. For example, in some example implementations, this method may reduce production cost by 31% to 46.2%, thereby enhancing the commercial potential of graphene. The method may additionally or alternatively address the limitation of recycled products by minimizing the costs associated with collecting and categorizing coffee residue. The amount of coffee residue required for this method is relatively small compared to the size of the final products, which may further streamline the manufacturing process. The growth process may involve high-temperature treatment, which eliminates the risk of disease spreading.

Further example implementations of method 100 in some embodiments are provided below as examples.

### Example 1

Place a Pt foil in a first quartz test tube and then place the first quartz test tube horizontally in the center of the downstream heating zone of the tube furnace. Then, place 1 mg of coffee residue (Robusta) in the second quartz test tube and then place the second quartz test tube horizontally in the center of the upstream heating zone of the tube furnace. The open sides of the two test tubes are connected to each other to form a semi-closed reaction chamber (e.g., FIG. 2). Provide a flow of argon (gas) to fully purge the air in the chamber, then adjust the flow rate of argon and hydrogen to 100 sccm and 2 sccm respectively. Next, heat up the downstream zone to 1000° C. at a rate of 50° C./min, then anneal for 30 minutes before heating up the upstream zone at a rate of 50° C./min. After the upstream zone reaches 600° C., both heating zones are maintained at their respective desired temperature for 20 minutes before cooling down naturally to collect the full-film 1L-graphene on the growth substrate.

### Example 2

Place a Cu foil in a first quartz test tube and then place the first quartz test tube horizontally in the center of the downstream heating zone of the tube furnace. Then, place 1 mg of coffee residue (Robusta) in the second quartz test tube and then place the second quartz test tube horizontally in the center of the upstream heating zone of the tube furnace. The open sides of the two test tubes are connected to each other to form a semi-closed reaction chamber (e.g., FIG. 2). Provide a flow of argon (gas) to fully purge the air in the chamber, then adjust the flow rate of argon and hydrogen to 200 sccm and 5 sccm respectively. Next, heat up the downstream zone to 1000° C. at a rate of 50° C./min, then anneal for 30 minutes before heating up the upstream zone at a rate of 50° C./min. After the upstream zone reaches 500° C., both heating zones are maintained at their respective desired temperature for 10 minutes before cooling down naturally to collect the full-film 1L-graphene on the growth substrate.

### Example 3

Place a Cu foil and then a Pt foil in a first quartz test tube and then place the first quartz test tube horizontally in the center of the downstream heating zone of the tube furnace. Then, place 2 mg of coffee residue (Robusta) in the second quartz test tube and then place the second quartz test tube horizontally in the center of the upstream heating zone of the tube furnace. The open sides of the two test tubes are connected to each other to form a semi-closed reaction chamber (e.g., FIG. 2). Provide a flow of argon (gas) to fully purge the air in the chamber, then adjust the flow rate of argon and hydrogen to 200 sccm and 10 sccm respectively. Next, heat up the downstream zone to 1040° C. at a rate of 50° C./min, then anneal for 30 minutes before heating up the upstream zone at a rate of 50° C./min. After the upstream zone reaches 600° C., both heating zones are maintained at their respective desired temperature for 10 minutes before cooling down naturally to collect the full-film 1L-graphene on the growth substrate.

The above examples can be modified to use other carbon-containing waste as the precursor for the synthesis of high-quality graphene.

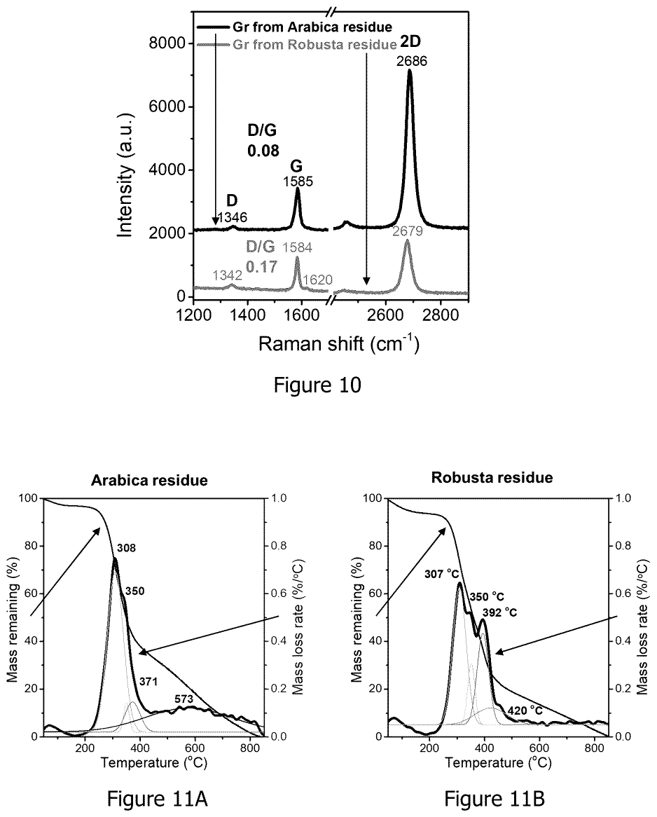

Experiments are conducted using different types of coffee residues, including Arabica and Robusta varieties as precursors. The results indicate the versatility of the process for using different biomass feedstocks. In this example, the Arabica-derived carbon precursor yields a high-quality 1L-graphene on Pt substrate with a Raman intensity ratio of I_{D}/I_{G}=0.08, as illustrated in FIG. 10, which is comparable to commercial single-layer graphene standards synthesized by a reference methane-source CVD method (I_{D}/I_{G}<0.1).

Further example implementations of method 100 in some embodiments are provided below as examples.

### Example 4

Place a Pt foil in a first quartz test tube and then place the first quartz test tube horizontally in the center of the downstream heating zone of the tube furnace. Then, place 1 mg of coffee residue (Arabica) in the second quartz test tube and then place the second quartz test tube horizontally in the center of the upstream heating zone of the tube furnace. The open sides of the two test tubes are connected to each other to form a semi-closed reaction chamber. Provide a flow of argon (gas) to fully purge the air in the chamber, then adjust the flow rate of argon and hydrogen to 100 sccm and 2 sccm respectively. Next, heat up the downstream zone to 1000° C. at a rate of 50° C./min, then anneal for 30 minutes before heating up the upstream zone at a rate of 50° C./min. After the upstream zone reaches 600° C., both heating zones are maintained at their respective desired temperature for 10 minutes before cooling down naturally to collect the full-film 1L-graphene on the growth substrate.

### Example 5

Place a Pt foil in a first quartz test tube and then place the first quartz test tube horizontally in the center of the downstream heating zone of the tube furnace. Then, place 1 mg of coffee residue (Robusta) in the second quartz test tube and then place the second quartz test tube horizontally in the center of the upstream heating zone of the tube furnace. The open sides of the two test tubes are connected to each other to form a semi-closed reaction chamber. Provide a flow of argon (gas) to fully purge the air in the chamber, then adjust the flow rate of argon and hydrogen to 100 sccm and 2 sccm respectively. Next, heat up the downstream zone to 1000° C. at a rate of 50° C./min, then anneal for 30 minutes before heating up the upstream zone at a rate of 50° C./min. After the upstream zone reaches 600° C., both heating zones are maintained at their respective desired temperature for 10 minutes before cooling down naturally to collect the full-film 1L-graphene on the growth substrate.

### Example 6

Place a Cu foil in a first quartz test tube and then place the first quartz test tube horizontally in the center of the downstream heating zone of the tube furnace. Then, place 1 mg of coffee residue (Arabica) in the second quartz test tube and then place the second quartz test tube horizontally in the center of the upstream heating zone of the tube furnace. The open sides of the two test tubes are connected to each other to form a semi-closed reaction chamber. Provide a flow of argon (gas) to fully purge the air in the chamber, then adjust the flow rate of argon and hydrogen to 100 sccm and 2 sccm respectively. Next, heat up the downstream zone to 1000° C. at a rate of 50° C./min, then anneal for 30 minutes before heating up the upstream zone at a rate of 50° C./min. After the upstream zone reaches 600° C., both heating zones are maintained at their respective desired temperature for 10 minutes before cooling down naturally to collect the full-film 1L-graphene on the growth substrate.

Thermogravimetric and derivative thermogravimetric (TGA/DTG) analysis has revealed that the decomposition rate of coffee residues may play a role in graphene quality. In one example implementation, as shown in FIGS. 11A and 11B, a stable decomposition rate of 0.01%/° C. to 0.15%/° C. at the annealing temperature range of 400° C. to 600° C. is considered as an optimal condition for producing high-quality 1L-graphene. The slow and controlled release of volatile carbonaceous species may ensure uniform carbon diffusion and nucleation across the metal substrate. This finding establishes a quantitative decomposition-growth correlation, providing a guide for adapting the implementation to other biomass-derived carbon sources such as but not limited to rice husk, coconut shell, or sugarcane bagasse for scalable graphene synthesis.

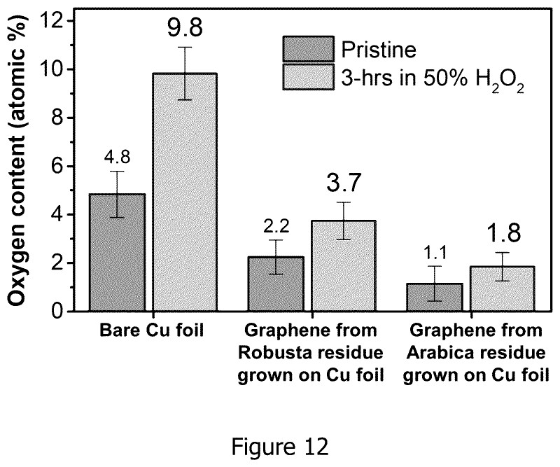

The functional benefits of the formed graphene films are evaluated. In one example implementation, a single-layer graphene grown on a Cu foil provides a fivefold enhancement in oxidation resistance compared with bare Cu 50% hydroperoxide (H₂O₂) solution, as shown in FIG. 12. This superior property may arise from the continuous, high-quality graphene coverage, which may effectively suppress chemical diffusion and surface oxidation. Such property can highlight the advantages of the approach in some examples, which include producing high-quality 1L-graphene from waste-derived feedstocks, and generating graphene coatings that can serve as sustainable anti-corrosion barriers for metal protection applications.

In some example implementations of method 100 in some embodiments, there is provided a method for directly growing 1L-graphene on a metal foil from coffee residue. During the process, coffee residue may be used as carbon source for the growth, metal foil may be used as a growth substrate, hydrogen gas may be used as reducing agent to prevent the oxidation on metal, and argon may be used as the carrier gas. A full-film graphene may be prepared using a multi-zone CVD system. Depending on implementations, the metal foil may include Pt foil and/or Cu foil, and it may have different sizes for different implementations. Depending on implementations, the coffee residue may originate from robusta coffee beans (e.g., any brands and processing). For example, the coffee residue may be used as collected after drying or undergo a treatment. The treatment may include, e.g., washing multiple times in hot water (60° C. to 100° C.) or/and ethanol (20° C. to 60° C.) then drying in oven (60° C. to 80° C.).

In some example implementations of method 100 in some embodiments, there is provided a method for directly growing 1L-graphene on a metal foil from coffee residue. The method may include: (1) Place a metal foil and a Pt foil in the first quartz test tube and then place the first quartz test tube horizontally in the center of the downstream heating zone of the tube furnace; (2) Place an amount of coffee residue in the second quartz test tube and then place the second quartz test tube horizontally in the center of the upstream heating zone of the tube furnace. Connect the open sides of the two quartz test tubes to each other to form a semi-close reaction chamber; (3) Provide a flow of argon (gas) to fully purge the air in the chamber, then adjust the flow rate of argon and hydrogen and set the heating programs for upstream and downstream zones; (4) Heat up the downstream zone and anneal for a certain period time before heating up the upstream zone to start the growth of graphene from coffee residue; (5) Turn off the upstream and downstream zones at the same time and cool down the chamber naturally to room temperature, then collect the full-film graphene grown on the metal substrate. In one example, the distance between the metal foil and the Pt foil in the first quartz test tube in (1) is in the range of 0.5 cm to 2 cm. In one example, the size of the first and second quartz test tubes in (1) and (2) are the same, and their sizes may be different for different examples, e.g. depending on the size of CVD chamber used for synthesis. In one example, the gas flow ratio of argon and hydrogen in (3) is in the range of 10:1 to 100:1. In one example, the set heating rate of both upstream and downstream zones in (3) is in the range of 20° C./min to 60° C./min. In one example, the desired temperature of downstream zone in (4) is in the range of 1000° C. to 1100° C. In one example, the downstream zone is heated up first and anneal for 30 minutes to 60 minutes prior to initiating the heat up of the upstream zone. In one example, the desired temperature of upstream zone in (4) is in the range of 300° C. to 600° C. and is maintained for 10 minutes to 60 minutes. In one example, the cooling rate in (5) is in the range of 10° C./min to 60° C./min.

Some embodiments disclosed herein utilize coffee residue, which is cheap and readily available, as precursors, thereby eliminating the need for expensive precursors and simplifying the process compared to some reference CVD graphene synthesis methods. That said, in some other embodiments, other types of solid biomass-derived carbon source may be used.

It will be appreciated by a person skilled in the art that variations or modifications may be made to the described and illustrated embodiments to provide further embodiments. The described and illustrated embodiments should therefore be considered in all respects as illustrative, not restrictive. For example, the metal substrate may include metal material not specifically disclosed herein. For example, the solid biomass-derived carbon source may include material not specifically disclosed herein. For example, the carrier gas may include gas not specifically disclosed herein. For example, the reducing gas may include gas not specifically disclosed herein. For example, the reducing gas may be omitted when another reducing means is present. For example, depending on specific implementations, the conditions (e.g., temperature, pressure, heating profile, gas flow rate, etc.) associated with the method may be modified.

1. A method of forming a graphene film based on chemical vapor deposition (CVD), comprising:
heating a metal substrate located in a first heating zone of a CVD reactor so as to enable graphene growth on the metal substrate;
heating a solid biomass-derived carbon source comprising volatilizable carbon-containing species located in a second heating zone of the CVD reactor so as to volatilize the carbon-containing species from the solid biomass-derived carbon source, the second heating zone being arranged upstream of and spatially separated from the first heating zone; and
providing a flow of carrier gas from the second heating zone to the first heating zone to facilitate transport of the volatilized carbon-containing species to the metal substrate, thereby enabling formation of a graphene film on the metal substrate;
wherein at least part of the heating of the metal substrate, at least part of the heating of the solid biomass-derived carbon source, and at least part of the providing of the flow of carrier gas are performed simultaneously.

2. The method of claim 1, wherein:
the metal substrate and the solid biomass-derived carbon source are arranged in a semi-closed reaction chamber;
the semi-closed reaction chamber comprises a first portion located in the first heating zone and a second portion located in the second heating zone; and
the semi-closed reaction chamber is configured to enable flow of the flow of carrier gas from the second portion to the first portion and to partially confine the volatilized carbon-containing species without pressure buildup.

3. The method of claim 2, further comprising, prior to heating the metal substrate, heating the solid biomass-derived carbon source, and providing the flow of carrier gas:
arranging the metal substrate in the first heating zone and the solid biomass-derived carbon source in the second heating zone by:
placing the metal substrate in a first container having open ends;
placing the solid biomass-derived carbon source in a second container having open ends; and
placing the first container in the first heating zone and the second container in the second heating zone such that the first container and the second container are connected at their open ends to define the semi-closed reaction chamber.

4. The method of claim 2, further comprising, prior to heating the metal substrate, heating the solid biomass-derived carbon source, and providing the flow of carrier gas:
purging the semi-closed reaction chamber.

5. The method of claim 1, wherein:
heating the metal substrate comprises heating the first heating zone in which the metal substrate is arranged; and
heating the solid biomass-derived carbon source comprises heating the second heating zone in which the solid biomass-derived carbon source is arranged.

6. The method of claim 5, wherein heating the first heating zone comprises heating the first heating zone at a first heating rate to reach a first temperature and then maintaining the first heating zone at approximately the first temperature.

7. The method of claim 6, wherein heating the second heating zone comprises heating the second heating zone at a second heating rate to reach a second temperature and then maintaining the second heating zone at approximately the second temperature.

8. The method of claim 7, wherein:
the second heating rate is the same as the first heating rate; and/or the second temperature is lower than the first temperature.

9. The method of claim 8, wherein:
the first heating rate is in a range of about 20° C./min to about 60° C./min;
a duration for the first heating zone to reach the first temperature is in a range of about 10 minutes to about 60 minutes;
the first temperature is in a range of about 1000° C. to about 1100° C.;
the second heating rate is in a range of about 20° C./min to about 60° C./min;
a duration for the second heating zone to reach the second temperature is in a range of about 10 minutes to about 60 minutes;
the second temperature is in a range of about 300° C. to about 600° C.; and/or
a decomposition rate of the solid biomass-derived carbon source due to the volatilization of the carbon-containing species is in a range of about 0.01%/° C. to about 0.15%/° C.

10. The method of claim 7, wherein the heating of the second heating zone at the second heating rate is initiated while the first heating zone is maintained at approximately the first temperature and after the first heating zone has been maintained at approximately the first temperature for a first period of time for annealing the metal substrate.

11. The method of claim 10, wherein the first heating zone is maintained at approximately the first temperature and the second heating zone is maintained at approximately the second temperature simultaneously for a second period of time.

12. The method of claim 11, wherein:
the first period of time is in a range of about 30 minutes to about 60 minutes; and/or
the second period of time is in a range of about 10 minutes to about 60 minutes.

13. The method of claim 11, further comprising, after the second period of time:
terminating heating of both the first heating zone and the second heating zone to enable cooling of the first heating zone and the second heating zone.

14. The method of claim 1, wherein the metal substrate comprises a platinum foil or a copper foil.

15. The method of claim 14, wherein the metal substrate comprises a first metal foil and a second metal foil separated by a distance.

16. The method of claim 1, wherein the solid, biomass-derived carbon source comprises lignocellulosic waste.

17. The method of claim 16, wherein:
the coffee residue comprises spent coffee grounds that has been dried prior to its heating; or
the coffee residue comprises spent coffee grounds that have been washed and then dried prior to its heating.

18. The method of claim 16, wherein an amount of the coffee residue prior to heating is in a range of about 0.1 mg to about 10 mg.

19. The method of claim 1, wherein the flow of carrier gas comprises an inert gas, and the method further comprising the step of providing a flow of reducing gas for preventing oxidation on or of the metal substrate, wherein the flow of reducing gas is combined with the flow of carrier gas as a combined flow; wherein:
a ratio of a flow rate of the inert gas to a flow rate of the reducing gas is in a range of about 10:1 to about 100:1;
a flow rate of the inert gas is in a range of about 100 sccm to about 200 sccm; and/or
a flow rate of the reducing gas is in a range of about 2 sccm to about 10 sccm.

20. The method of claim 19, further comprising transferring the graphene film formed on the metal substrate to a target substrate using an electrochemical delamination process; and wherein the graphene film comprises a single-layer (1L) graphene film.
